(19) United States
(12) Patent Application Publication
(10) Pub. No.: US 2020/0303353 A1
(43) Pub. Date: Sep. 24, 2020

(54) PANEL LIGHT

(71) Applicant: Jinsheng DENG, Rancho Dominguez, CA (US)

(72) Inventor: Jinsheng DENG, Rancho Dominguez, CA (US)

(73) Assignee: EVERY INDUSTRY LLC

(21) Appl. No.: 16/361,226

(22) Filed: Mar. 22, 2019

(51) Int. Cl. H01L 25/075; F21V 5/04; F21V 15/01; F21K 9/69; H05K 1/18

(52) U.S. Cl. CPC H01L 25/0753; F21V 5/04; F21Y 2115/10; F21K 9/69; H05K 1/181; F21V 15/01

(57) ABSTRACT

A panel light with a simple structure and uniform luminescence comprises a framework, a framework and a casing and a panel installed on the framework; the casing having a chamber disposed therein; the chamber having illuminants for lighting; the illuminant includes a circuit board, a LED chip for emitting light integrated on the circuit board and a lens covering the LED chip; the lens is integrally formed with a surface having a convex curved surface and a bottom surface attached to the circuit board, a recess disposed along a center of the bottom surface for accommodating the LED chip; the lens is fixed on the circuit board, and the LED chip is covered by the recess, and the light generated by the LED chip passes through the lens and is then illuminated through the panel.

### BACKGROUND OF INVENTION

### 1. Field of the Invention

This project relates generally to a panel light with a simple structure and uniform luminescence.

### 2. Description of Related Art

The panel light is extensively used for indoor lighting for large luminous surface. General panel light comprises a framework made of aluminum alloy material, a panel installed on the lower surface of framework and a casing installed on the upper end of framework. At present, the illuminant of panel light uses LED chips as light source. In order to obtain more uniform and wider luminescence, the general illuminant mode is that multiple LED chips are distributed uniformly on the circuit board, as the light rays emitted from the LED chips are point source, which cannot be directly used as area light source. Therefore, to make these arrayed LED chips emit soft light rays, a panel is required to guide the light rays. The panel is usually made of plastic materials with better optical activity. The light rays are refracted by the panel to form a more uniform and softer light source.

At present, in the manufacture of LED panel light, the optical structure of panel is improved to enhance the luminescent effect of panel light. This project proposes improving the luminescent effect of each LED chip directly, so as to enhance the luminescent effect of overall panel light. Based on this, this project proposes the following technical proposal.

### SUMMARY OF THE INVENTION

The purpose of the present invention is to overcome the deficiencies in the existing technology to provide a panel light with a simple structure and uniform luminescence.

In order to solve the above problems, the technical scheme of the present invention is described below:

A panel light, comprising a framework and a casing and a panel installed on the framework; the casing having a chamber disposed therein; the chamber having illuminants for lighting wherein the illuminant includes a circuit board, a LED chip for emitting light integrated on the circuit board and a lens covering the LED chip;

wherein the lens is integrally formed with a surface having a convex curved surface and a bottom surface attached to the circuit board, a recess disposed along a center of the bottom surface for accommodating the LED chip;

wherein the lens is fixed on the circuit board, and the LED chip is covered by the recess, and the light generated by the LED chip passes through the lens and is then illuminated through the panel.

More particularly, wherein a central position of the surface of the lens forms a concave surface.

More particularly, wherein a cross section of an inner surface of the recess of the lens forms a parabolic curve.

4 More particularly, wherein the parabolic curve converges at a central vertex of an inner surface opposite to an opening of the recess.

More particularly, wherein the lens has a bulge outwards along the bottom surface, the bulge has a positioning lug connected to the circuit board.

More particularly, wherein the circuit boards are uniformly mounted on the inner surface of the casing, and LED chips are evenly distributed on each of the circuit boards

More particularly, wherein the framework is a rectangular framework, an inner frame is formed along the edges of framework, the mounting edges corresponding to the inner frame are formed on the edges of the casing, a hold-down frame protruding downward is formed along the inner side of mounting edges.

In comparison with the existing technology, this project has the following effects:

In this project, each LED chip is covered with a lens, the lens refracts the light rays generated by the LED chip, the illumination angle of the original LED chip is changed, so that a larger range of irradiation is formed after the light rays penetrate through the lens. When these light rays irradiate the panel, more uniform luminescent effect is formed.

This project has a very simple structure, the panel can be fixed without screws or buckles. When the casing is fixed, the casing holds down the panel to fix the panel into the framework.

### BRIEF DESCRIPTION OF THE DRAWINGS:

FIG. 1 is a schematic view of a panel light of the present invention;

FIG. 2 is a schematic of the light of the present invention without panel;

FIG. 3 is a three-dimensional exploded view of the panel light of the present invention;

FIG. 4 is a sectional view of an illuminant of the present invention;

FIG. 5 is a schematic of back view of the present invention.

### DETAILED DESCRIPTION OF THE INVENTION

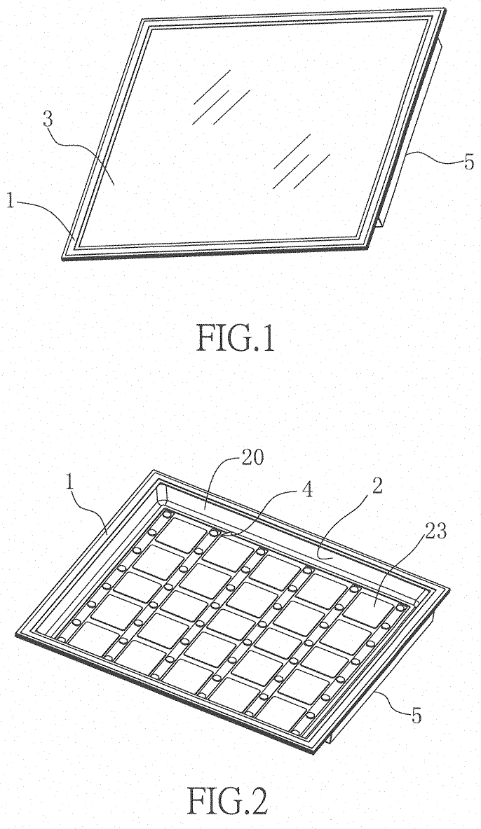

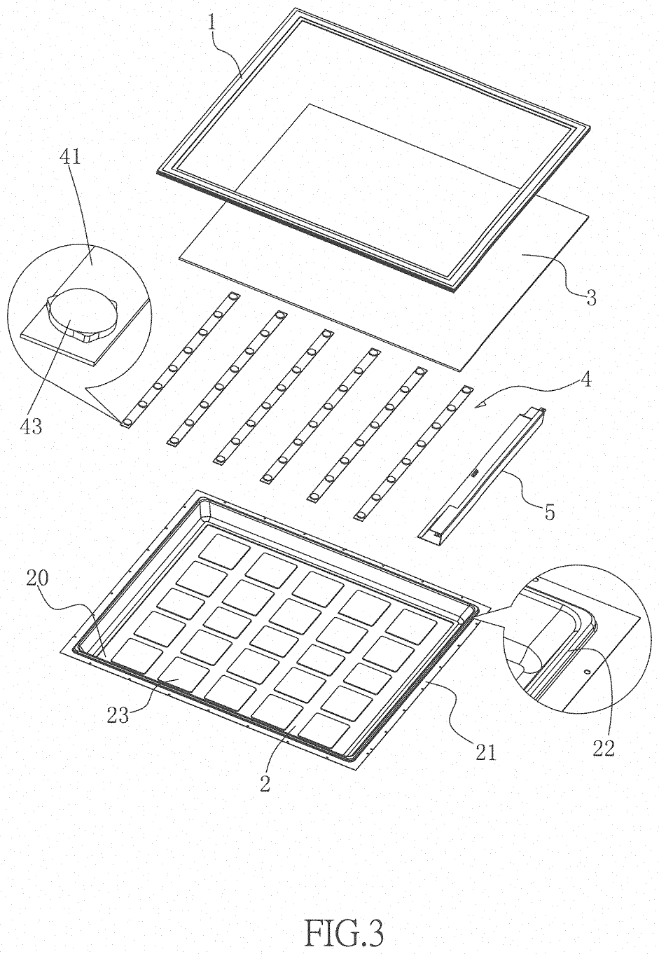

As shown in FIG. 1 to FIG. 5, a panel light comprises a framework 1, a casing 2, a panel 3, illuminants 4 and a supply unit 5.

Said framework 1 is generally a rectangular framework, made of aluminum alloy or POM. The casing 2 and panel 3 are fixed to the framework 1. A chamber 20 is formed in the casing 2. The illuminants 4 are located in the chamber 10. The supply unit 5 is fixed to a side of casing 2. Certainly, the supply unit 5 can be fixed to the framework 1 or installed in other positions. The supply unit 5 is connected to the circuit board of illuminants 4 by conductors.

An inner frame 11 is formed along the edges of framework 1. The mounting edges 21 corresponding to the inner frame 11 are formed on the edges of said casing 2. A hold-down frame 22 protruding downward is formed along the inner side of mounting edges 21.

An open area is formed in the center of said framework 1. An inner frame 11 is formed on the edges of framework 1. The region surrounded by the inner frame 11 exactly corresponds to the size of casing 2. Said casing 2 is placed in the inner frame 11 of framework I directly. The mounting edges 21 corresponding to the inner frame 11 are formed on the edges of said casing 2. The mounting edges 21 are provided with threaded holes 210. In addition, a hold-down frame 22 protruding downward is formed along the inner side of mounting edges 21.

During installation, the panel 3 is placed above the open area of framework 1, and then the casing 2 is placed in the inner frame 11 of framework 1. The screws pass through the threaded holes 210 to fix the mounting edges 21 into the inner frame 11. When the casing 2 is fixed to the top of framework 1 by screws, the hold-down frame 21 exactly holds down the panel 3 in the framework 1, the assembly of overall panel light is finished.

Said illuminant 4 comprises a circuit board 41, a LED chip 42 for emitting light integrated on the circuit board 41 and a lens 43 covering LED chip 42.

Said circuit board 41 is fixed to the inner surface of casing 2, and multiple strip-like circuit boards 41 are fixed uniformly on the inner surface of casing 2, there are LED chips 42 distributed uniformly on each circuit board 41. In order to enhance the strength of casing 2, there are reinforcing lugs 23 formed on the inner surface of casing 2. These reinforcing lugs 23 behave as stiffeners, enhancing the deformation strength of inner surface of overall casing 2, and restraining the installation of circuit board 41.

Said lens 43 is formed integrally, it has a convex surface 431 and a bottom surface 432 adhering to the surface of circuit board 41. A recess 430 for holding the LED chip 42 is provided in the center of said bottom surface 432. Said lens 43 is fixed to the circuit board 41, and the recess 430 covers the LED chip 42, the light rays generated by LED chip 42 penetrate through the lens 43 and through the panel 3.

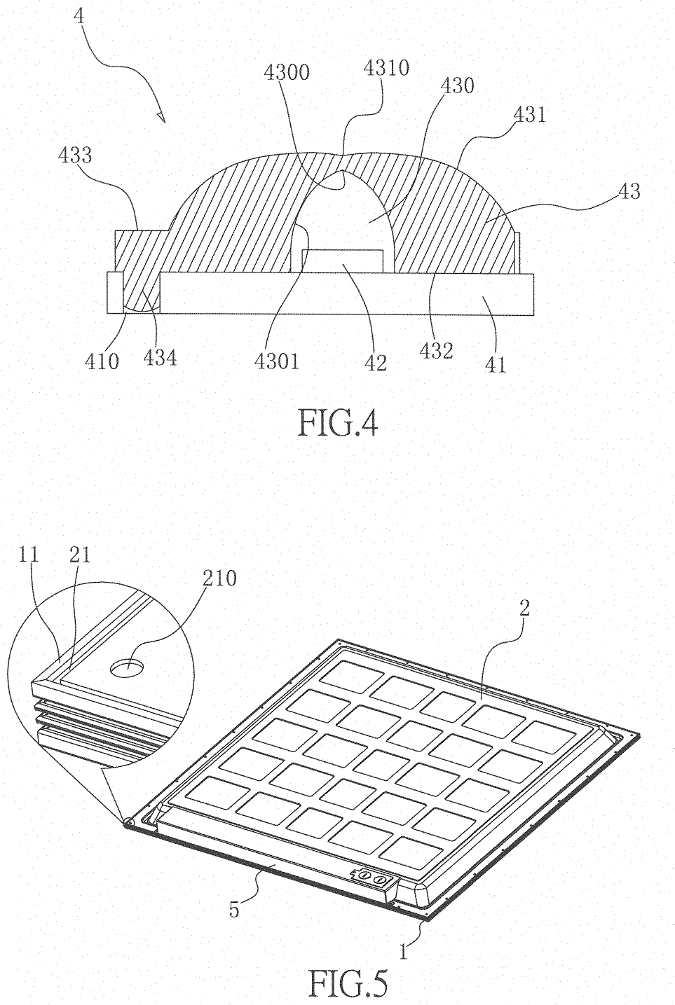

As shown in FIG. 4, a concave surface 4310 is formed in the center of surface 431 of said lens 43, which is to say, an inflection point is formed in the central area of surface 431 of lens 43, the light rays in the central area are diffused more effectively, resulting in more uniform luminescence,

In addition, the cross section of inner surface of recess 430 of said lens 43 is a parabolic curve 4301. Said parabolic curve 4301 converges at the central vertex 4300 opposite to the opening of recess 430 of inner surface 4301.

For convenient installation, said lens 43 has a bulge 433 outwards along the bottom surface 432, The bulge 433 has a positioning lug 434 connected to the circuit board 41. In the installation of lens 43, a location hole corresponding to the positioning lug 434 can be formed on the circuit board directly, the lens is fixed to the circuit board 41 by clamping.

I claim

1. A panel light, comprising a framework (1) and a casing (2) and a panel (3) installed on the framework (1), the casing (2) having a chamber (20) disposed therein; the chamber (20) having illuminants (4) for lighting wherein the illuminant (4) includes a circuit board (41), a LED chip (42) for emitting light integrated on the circuit board (41) and a lens (43) covering the LED chip (42);
wherein the lens (43) is integrally formed with a surface (431) having a convex curved surface and a bottom surface (432) attached to the circuit board (41), a recess (430) disposed along a center of the bottom surface (432) for accommodating the LED chip (42);
wherein the lens (43) is fixed on the circuit board (41), and the chip (42) is covered by the recess (430), and the light generated by the LLD chip (42) passes through the lens (43) and is then illuminated through the panel (3).

2. The panel light defined in claim 1, wherein a central position of the surface (431) of the lens (43) forms a concave surface (4310).

3. The panel light defined in claim 1, wherein a cross section of an inner surface of the recess (430) of the lens (43) forms a parabolic curve (4301).

4. The panel light defined in claim 3, wherein the parabolic curve (4301) converges at a central vertex (4300) of an inner surface opposite to an opening of the recess (430).

5. The panel light defined in claim 1, wherein the lens (43) has a bulge (433) outwards along the bottom surface (432), the bulge (433) has a positioning lug (434) connected to the circuit board (41).

6. The panel light defined in claim 1, wherein the circuit boards (41) are uniformly mounted on the inner surface of the casing (2), and LED chips (42) are evenly distributed on each of the circuit boards (41).

7. The panel light defined in claim 1, wherein the framework (1) is a rectangular framework, an inner frame (11) is formed along the edges of framework (1), the mounting edges (21) corresponding to the inner frame (11) are formed on the edges of the casing (2), a hold-down frame (22) protruding downward is formed along the inner side of mounting edges (21).
